(19) United States
(12) Patent Application Publication
(10) Pub. No.: US 2006/0105483 A1
(43) Pub. Date: May 18, 2006

(54) Encapsulated light emitting diodes and methods of making

(76) Inventors: Catherine A. Leatherdale, St. Paul, MN (US); David Scott Thompson, Woodbury, MN (US); Larry D. Boardman, Woodbury, MN (US); Rajdeep S. Kalgutkar, St. Paul, MN (US)

Correspondence Address: 3M INNOVATIVE PROPERTIES COMPANY, PO BOX 33427, ST. PAUL, MN, 55133-3427, US

(21) Appl. No.: 10/993,549

(22) Filed: Nov. 18, 2004

(51) Int. Cl. H01L 21/00

(52) U.S. Cl. 438/26; 257/E33.059; 257/E33.073; 438/27

(57) ABSTRACT

Methods for making encapsulated light emitting diodes, and light emitting articles prepared thereby are disclosed. The methods include activating a light emitting diode to emit light to at least partially polymerize a photopolymerizable encapsulant.

### BACKGROUND

A light emitting diode (LED) includes a semiconductor chip with two regions separated by a p-n junction. The junction allows current to flow only in one direction. When a positive bias electrical voltage is applied to the LED, light is emitted in the form of photons.

Light emitting diodes have a number of advantages as light sources, such as relatively cool operating temperatures, high achievable wall plug efficiencies, and a wide range of available emission wavelengths distributed throughout the visible and also in the adjacent infrared and ultraviolet regions depending upon the choice of semiconductor material.

Because of the relatively large refractive index of most LED light-generating materials (refractive index n>2 in most cases), the internally generated light rays incident upon the light emitting diode surface at angles greater than the critical angle experience total internal reflection and do not pass through the light emitting diode surface. A transparent encapsulant, typically in the shape of a hemispherical dome, is used to improve external light coupling. The encapsulant material is typically an epoxy resin with a refractive index of approximately 1.5. The encapsulant improves light extraction by increasing the critical angle, thereby reducing total internal reflection losses.

The epoxy encapsulant is typically thermally cured to form a packaged LED with electrical leadwires or pins, which leadwires are subsequently connected to a circuit board or other external electrical circuit typically by a high temperature process such as soldering. The thermal cure step has several disadvantages including, for example, the potential for formation of trapped gas bubbles, resin shrinkage, and long curing times. Moreover, the choice of encapsulating materials is limited to those that may withstand the high temperatures used during soldering.

Applicants have identified a need for methods of increasing the light extraction efficiency of LEDs that do not suffer from one or more drawbacks of existing methods.

### BRIEF SUMMARY

The present application discloses several types of encapsulated LEDs and methods associated therewith. In some embodiments, the encapsulant of an LED package is self-cured by energizing the LED die, which can result in the highest degree of cure for the encapsulant being achieved closest to the die. This can be important for encapsulants that, in addition to photoinitiated curing, either have a reaction mechanism that liberates small molecules upon curing, or contain other small molecules that can diffuse during the curing reaction. The gelation of the region closest to the die allows these small molecules to diffuse more easily through the uncured region of the encapsulant. Additionally, such curing can result in initial curing of the material occurring closest to the die, then progressing away from the die. This can reduce or limit mechanically generated stress within the encapsulant. Controlling mechanical stress in this way can be important for encapsulants that have a high tensile modulus, weak bond strength to the die, or both.

Disclosed LED packages can be electrically connected to a circuit board or other final substrate prior to encapsulation. This approach makes possible the use of encapsulant compositions that may bubble or otherwise degrade if subjected—even briefly—to the elevated temperatures used in soldering.

Disclosed encapsulant materials and methods that produce a graded refractive index in the encapsulant can provide particular utility for surface mount and side mount LED packages where the encapsulant is cured in a reflector cup, and where the encapsulant-air interface is substantially flat, and parallel to the emitting surface of the light emitting diode die. For encapsulants having a curved air/encapsulant interface such as a hemisphere or other lens-like shape, providing the encapsulant with a graded refractive index can reduce the amount of Fresnel reflection at the interface.

Disclosed self-curing processes, where the encapsulant is cured by energizing the LED, can also be used to bond a packaged LED to a waveguide. For example, many handheld displays require that at least one LED be coupled to a thin waveguide. Simple coupling of the LED to the waveguide with an adhesive may result in light being lost at the bond site. Using the LED-emitted light itself to cure the resin to form a bond between the LED and the waveguide may simplify the manufacturing process, while creating the highest index regions between the LED and the waveguide. This may happen even if the illumination is relatively uniform, if two monomers with substantially different refractive indices are being cured. In such a situation a low refractive index cladding around the bond site between the LED and the waveguide may be formed in situ.

These and other aspects of the disclosed embodiments will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

FIGS. 1 (A)-(D) show in schematic cross-section a sequence of views of an LED package depicting the formation of a self-aligned graded refractive index (“GRIN”) encapsulant lens.

### DETAILED DESCRIPTION OF ILLUSTRATIVE EMBODIMENTS

Various light emitting articles and methods of making light emitting articles are taught herein. Many have applicability to light emitting diodes.

“Light emitting diode” or LED in this regard refers to a diode that emits light, whether visible, ultraviolet, or infrared. It includes incoherent epoxy-encased semiconductor devices marketed as “LEDs”, whether of the conventional or super-radiant variety. Vertical cavity surface emitting laser diodes are another form of light emitting diode. An “LED die” is an LED in its most basic form, i.e., in the form of an individual component or chip made by semiconductor wafer processing procedures. The component or chip can include electrical contacts suitable for application of power to energize the device. The individual layers and other functional elements of the component or chip are typically formed on the wafer scale, the finished wafer finally being diced into individual piece parts to yield a multiplicity of LED dies.

In some methods, an encapsulated LED package is made by placing a volume or quantity of photopolymerizable encapsulant in contact with an LED and then activating the LED to at least partially polymerize the photopolymerizable encapsulant with the light emitted by the LED. In some embodiments the entire volume or thickness of the photopolymerizable encapsulant is at least partially polymerized. Typically, the thickness is at least a factor of 1 or 2 times the thickness of the LED die. Partial polymerization can include transforming an initially liquid encapsulant material to a gel state, and beyond if desired to a substantially solid state. The partially polymerized encapsulant material can resist attack by solvents in that it will not be removed by washing with solvent. Such methods can also be used, for example, to bond an encapsulated LED to a waveguide by contacting the waveguide with the photopolymerizable encapsulant before activating the LED. In some embodiments, the LED is provided in a mold (e.g., a reflector cup), and a volume of the photopolymerizable encapsulant fills the mold. In other embodiments, the LED is provided on a substrate. Optionally, the encapsulant can be further polymerized by heating and/or irradiation with an external light source. Typically, the photopolymerizable encapsulant includes a photoinitiator system.

In some embodiments, the photopolymerizable encapsulant includes a polymerizable component and a non-polymerizable component (e.g., polymers or nanoparticles) that can phase separate at least partially when the LED is activated to at least partially polymerize the photopolymerizable encapsulant. Preferably the refractive index of the polymerizable component is different than the refractive index of the non-polymerizable component, in which case a graded refractive index encapsulant can result. Such embodiments can be useful for making light emitting articles having a self-aligned graded refractive index (GRIN) lens. Self-aligned in this regard means that a structure or form, such as the graded refractive index, is substantially aligned with the radiation flux from the LED or other light source.

Depending upon the choice of the refractive index of the polymerizable and non-polymerizable components, their relative diffusion rates, and the angular distribution of light emitted from the LED die, either a positive or a negative self-aligned graded refractive index (GRIN) lens for the light emitting diode may be fabricated. For example, if the polymerizable species has a higher refractive index and the LED die emits light predominately from its upper or topmost surface, a positive, or converging lens may be created. If the reactive species has a lower refractive index, a negative, or diverging lens may be created.

Photopolymerizable Encapsulant

Photopolymerizable encapsulants as disclosed herein include a polymerizable component. As used herein, “polymerizable” is meant to encompass materials that can be polymerized, crosslinked, and/or otherwise reacted to form a matrix. Suitable polymerizable components include monomers, oligomers, and/or polymers. The photopolymerizable encapsulant typically includes a photoinitiator system.

Suitable polymerizable components are materials that typically have a low viscosity prior to cure, but can preferably be rapidly polymerized upon exposure to the wavelength of light emitted by the LED. The low viscosity allows the LED to be embedded in the encapsulant without, for example, excessive formation or entrapment of gas or air bubbles. Once polymerized, the encapsulant preferably is resistant to thermal and photodegradation (e.g., yellowing) and provides adequate mechanical and environmental stability for the LED die and associated electrical contacts.

Typical polymerizable components may be mono-, di-, tri-, tetra- or otherwise multifunctional in terms of polymerizable moieties. Suitable polymerizable components include, for example, epoxy functional materials, (meth)acrylate functional materials, organosiloxanes (including silicones and other organopolysiloxanes), and combinations thereof. As used herein, “(meth)acryl” is a shorthand term referring to “acryl” and/or “methacryl.” For example, a “(meth)acryloxy” group is a shorthand term referring to either an acryloxy group (i.e., CH₂═CHC(O)O—) and/or a methacryloxy group (i.e., CH₂═C(CH₃)C(O)O—).

Epoxy functional materials and (meth)acrylate functional materials suitable for the polymerizable component include, for example, those disclosed in U.S. Patent Application Publication No. 2004/0012872 (Fleming).

Preferred epoxy functional materials for making GRIN encapsulants include monomers and/or resins having high refractive index, including aromatic, mono, di-, and higher epoxide functionality, including for instance, aromatic glycidyl epoxies (such as phenyl glycidyl ether and the Epon™ resins available from Resolution Performance Products), fluorene based epoxies (such as those derived from the biscresol and bisphenol of fluorene), brominated epoxies, cycloaliphatic epoxies (such as ERL-4221 and ERL-4299 available from Union Carbide), phenol novolak epoxies, and homogeneous mixtures thereof. These epoxy resins can have additional components such as acid anhydrides, curing accelerators, antioxidants and hardeners. Exemplary (meth)acrylate monofunctional materials for making GRIN encapsulants include those with substituted and unsubstituted aromatic groups, such as 2-(1-napthoxy)ethyl (meth)acrylate, 2-(2-napthoxy)ethyl acrylate, phenoxyethyl (meth)acrylate, alkoxylated nonylphenol acrylate, and 9-phenanthrylmethyl (meth)acrylate. Multifunctional polymerizable monomers comprising on average greater than one polymerizable group per molecule may also be incorporated into the encapsulant composition to enhance one or more properties of the cured structures, including crosslink density, hardness, tackiness, mar resistance and the like. Exemplary multifunctional (meth)acrylates for making GRIN encapsulants include those with substituted and unsubstituted aromatic groups, such as ethoxylated bisphenol A di(meth)acrylate, aromatic urethane (meth)acrylates and aromatic epoxy (meth)acrylates.

Various organosiloxanes are examples of another class of photopolymerizable materials suitable for preparing the disclosed encapsulants. These silicon-containing resins are preferably mixtures of one or more linear, cyclic, or branched organosiloxanes comprising units of the formula R¹ₐR²_{b}SiO_{(4-a-b)/2} where

R¹ is a monovalent, straight-chain, branched or cyclic, unsubstituted or substituted hydrocarbon radical which is free of polymerizable functionality and has from 1 to 18 carbon atoms per radical;

R² is a functional group that can participate in a polymerization or crosslinking reaction or a hydrocarbon radical containing from 1 to 18 carbon atoms which contains a functional group that can participate in a polymerization or crosslinking reaction;

a is 0, 1, 2 or 3;

b is 0, 1, 2 or 3;

and the sum a+b is 0, 1, 2 or 3, with the proviso that there is on average at least 1 radical R² present per molecule.

Organosiloxanes that contain aliphatic unsaturation preferably have an average viscosity of at least 5 mPa.s at 25° C. Examples of suitable radicals R¹ are alkyl radicals such as methyl, ethyl, n-propyl, iso-propyl, n-butyl, iso-butyl, tert-butyl, n-pentyl, iso-pentyl, neo-pentyl, tert-pentyl, cyclopentyl, n-hexyl, cyclohexyl, n-octyl, 2,2,4-trimethylpentyl, n-decyl, n-dodecyl, and n-octadecyl; aromatic radicals such as phenyl or naphthyl; alkaryl radicals such as 4-tolyl; aralkyl radicals such as benzyl, 1-phenylethyl, and 2-phenylethyl; and substituted alkyl radicals such as 3,3,3-trifluoro-n-propyl, 1,1,2,2-tetrahydroperfluoro-n-hexyl, and 3-chloro-n-propyl.

For some embodiments, organosiloxane resins described above wherein a significant fraction of the R¹ radicals are phenyl or other aryl, aralkyl, or alkaryl are desirable, because the incorporation of these radicals provides materials having higher refractive indices than materials wherein all of the R¹ radicals are, for example, methyl.

Various types of photopolymerizable organosiloxanes are known and include, for example, epoxy-functional organosiloxanes, hydrosilylation curable organosiloxanes, acrylate- and methacrylate-functional organosiloxanes, ene-thiol organosiloxanes, and vinyl ether-functional organosiloxanes.

Suitable epoxy-functional organosiloxanes are disclosed in, for example, U.S. Pat. Nos. 4,313,988 (Koshar et al), 5,332,797 (Kessel et at), 4,279,717 (Eckberg et at), and 4,421,904 (Eckberg et at). Suitable hydrosilylation curable organosiloxanes are disclosed in, for example, U.S. Pat. Nos. 3,169,662 (Ashby), 3,220,972 (Lamoreauz), 3,410,886 (Joy), and 4,609,574 (Keryk), and the photohydrosilylation curing of these materials is disclosed in, for example, U.S. Pat. Nos. 6,376,569 (Oxman et at), 4,916,169 (Boardman et at), 6,046,250 (Boardman et at), 5,145,886 (Oxman et at), 6,150,546 (Butts), 4,30,879 (Drahnak), 4,510,094 (Drahnak), 5,496,961 (Dauth et at), 5,523,436 (Dauth et at), and 4,670,531 (Eckberg), as well as International Publication No. WO 95/025735 (Mignani et at). Suitable acrylate- and methacrylate-functional organosiloxanes are disclosed in, for example, U.S. Pat. Nos. 5,593,787 (Dauth et al), 5,063,254 (Nakos), 5,494,979 (Ebbrecht et at), and 5,092,483 (Mazurek et at). Suitable enethiol organosiloxanes are disclosed in, for example, U.S. Pat. Nos. 5,063,102 (Lee et at) and 5,169,879 (Lee et at). Suitable vinyl ether-functional organosiloxanes are disclosed in, for example, U.S. Pat. Nos. 5,270,423 (Brown et at) and 5,331,020 (Brown et at).

Also of utility with the disclosed light emitting devices are organosiloxane compositions that utilize a combination of the photopolymerization chemistries listed above. One example of such so-called “dual cure” formulations containing both epoxy functionality and acrylate functionality is given by U.S. Pat. No. 4,640,967 (Eckberg et at).

In some embodiments, particularly those providing a graded refractive index, the photopolymerizable encapsulant further includes a non-polymerizable component. Some non-polymerizable components (e.g., polymers and/or nanoparticles) can at least partially phase separate when photocuring is initiated to at least partially polymerize the photopolymerizable encapsulant. If the refractive index of the polymerizable component is different than the refractive index of the non-polymerizable component, a graded refractive index encapsulant can result. Significantly, the refractive index profile can be controlled through appropriate choice of one or more factors such as the glass transition temperature of the binder, monomer or nanoparticle size (in order to control the diffusion rate), and temperature of the encapsulant during photocuring. For instance, because the distance a monomer molecule can diffuse depends to some degree on its probability of reaction with a growing polymer chain, diffusion can be controlled by controlling such factors as the curing time and the photocuring flux or intensity, which in self-curing embodiments is a function of the current applied to the LED during cure. Since diffusion is a function of molecular weight, shape, and size, monomer diffusion can be controlled by controlling the molecular weight, shape and size of the monomer or monomers. Diffusion can also be controlled by controlling the viscosity of the monomer or monomers. Since viscosity and other properties vary with temperature, the use of temperature together with other factor(s) as control mechanisms at the same time may produce complex interactions.

Another variable is the time between a first self-curing step involving only light emitted by the LED itself, and an optional blanket photocuring step involving irradiation of substantially the entire encapsulant volume with at least one external light source. Advantageously, blanket irradiation promotes dimensional and chemical stability of the graded refractive index structure. Continued diffusion over time can change the three dimensional shape of the refractive index profile. But blanket irradiation can polymerize most, if not all, of the polymerizable species in the composition, rendering the composition chemically inert with respect to further irradiation, heating, or chemical reaction involving polymerization or crosslinking thereby providing stable reliable optical elements/devices.

The reader will understand that the fabrication of GRIN encapsulant structures involves careful tradeoffs between the magnitude of the refractive index profile created and the potential for absorption of the emitted LED light by the polymerizable species. For example, while the use of aromatic monomers can yield a large refractive index contrast, the aromaticity also can increase the absorption of the encapsulant in the UV and blue regions of the electromagnetic spectrum.

Nanoparticles suitable for use as a non-polymerizable component of the photopolymerizable encapsulant are preferably on the order of nanometers in size, substantially inorganic in chemical composition, and largely transparent at the emission wavelength of the LED. Such particles include metal oxides such as Al₂O₃, ZrO₂, TiO₂, ZnO, SiO₂, combinations thereof, as well as other sufficiently transparent non-oxide ceramic materials such as semiconductor materials including such materials as ZnS, CdS, and GaN. Silica (SiO₂), having a relatively low refractive index, may also be useful as a particle material in some applications, but, more significantly, it can also be useful as a thin surface treatment for particles made of higher refractive index materials, to allow for more facile surface treatment with organosilanes. In this regard, the particles can include a core of one type of material on which is deposited a shell of another type of material. Alternatively they can be composed of clusters of smaller particles. Generally, the particles or clusters are smaller than the wavelength of light. Preferably, the nanoparticles have sizes (average particle diameter) in the range from 1 nanometer to 1 micron, more preferably from 3 nanometers to 300 nanometers, even more preferably from 5 to 150 nanometers or from 5 to 75 nanometers.

Such particles can be surface modified, preferably with an organic material. Surface modification can enhance the compatibility of the particles with the resin, which may retard aggregation that can result in haze. The surface modification material(s) also can have reactive functionality. Reactive particles can be included in the polymerizable component for adjusting refractive index. It is also contemplated to use two different types of particles in the encapsulant. For example, one particle type can comprise a high refractive index material, such as zirconia, and another particle type can comprise a low refractive index material, such as silica. They can be functionalized such that either of the particles types, for example the high refractive index particle, is reactive and the other, low refractive index particle, is non-reactive and capable of diffusion (or vice versa) to create the corresponding positive (or negative) graded refractive index profile.

To the extent that the surface modifier has a lower refractive index than the particle core, the volume occupied by the surface modifier lowers the effective refractive index of the particle. Surface modification of the particles can be effected by various known techniques, such as those described in U.S. Pat. Nos. 2,801,185 (Iler) and 4,522,958 (Das et al.). For example, silica particles can be treated with monohydric alcohols, polyols, or mixtures thereof (preferably, a saturated primary alcohol) under conditions such that silanol groups on the surface of the particles chemically bond with hydroxyl groups to produce surface-bonded ester groups. The surface of the silica (or other metal oxide) particles can also be treated with organosilanes, e.g, alkyl chlorosilanes, trialkoxy arylsilanes, or trialkoxy alkylsilanes, or with other chemical compounds, e.g., organotitanates, which are capable of attaching to the surface of the particles by a covalent or ionic chemical bond or by a strong physical bond, and which are chemically compatible with the chosen resin(s). For silica, treatment with organosilanes is generally preferred. When aromatic ring-containing epoxy resins are utilized, surface treatment agents that also contain at least one aromatic ring are generally compatible with the resin and are thus advantageous. Similarly, other metal oxides can be treated with a variety of organic acids (for example, carboxylic acids and phosphonic acids). The organic acid can also be incorporated into the composition as a dispersant. The surface modified layer is usually made as thin as practicable but typically is at least 6 Angstroms thick.

A non-diffusing binder component incorporated into the encapsulant composition as the non-polymerizable component can provide numerous benefits. For instance, a non-diffusing binder component can help to reduce shrinkage upon curing, and improve resilience, toughness, cohesion, adhesions, tensile strength, and the like. Preferably the non-diffusing binder component is miscible with the polymerizable component both before and after it is cured. It is also preferred that the non-diffusing binder component is at least substantially non-crystalline before and after the polymerizable component is cured.

Suitable polymers for the non-diffusing binder component include straight chain polymers, branched chain polymers, and highly branched polymers (e.g., hyperbranched polymers). Both thermoplastic and thermosetting polymers may be used. Preferably, the polymer has a molecular weight of at least 1000, preferably 1000 to 2,000,000 g/mol or more. Useful thermoplastic polymers may include acrylates and methacrylates, poly(vinyl esters), ethylene/vinyl acetate copolymers, styrenic polymers and copolymers, cellulose esters, and cellulose ethers, as described in European Patent Publication 377,182 A2 (Smothers et al.) and U.S. Pat. No. 4,963,471 (Trout et al.).

Preferred polymers for use as non-polymerizable components include, for example cellulose acetate butyrate such as the CAB-531 material commercially available from Eastman Chemical, Kingsport, Tenn.

Photopolymerizable encapsulants typically include a photoinitiator system capable of inducing polymerization of the polymerizable component upon exposure to a wavelength of light emitted from the LED. Suitable photoinitiator systems, as further described herein below, will depend on the nature of the polymerizable component and the wavelength of light emitted from the light emitting diode. Suitable photoinitiator systems for the disclosed encapsulants are generally initially absorbing at a wavelength of light emitted from the LED. If the photoinitiator system is initially visibly colored, preferably the color bleaches upon photoreaction. For example, photoinitiator systems that are initially colored may include, as one of the components (e.g., a sensitizer) of the system, a dye that is photobleachable. Exemplary photobleachable dyes are disclosed, for example, in U.S. Pat. Nos. 6,444,725 (Trom et al.) and 6,528,555 (Nikutowski et al.). Exemplary photobleachable dyes include Rose Bengal, Methylene Violet, Methylene Blue, Fluorescein, Eosin Yellow, Eosin Y, Ethyl Eosin, Eosin bluish, Eosin B, Erythrosin B, Erythrosin Yellow Blend (90% Erythrosine B and 10% Erythrosine Y), Erythrosin Yellow, Toluidine Blue, 4′, 5′-Dibromofluorescein and blends thereof.

Photoinitiator systems that can induce radical and/or cationic polymerization upon exposure to light are useful when the polymerizable component includes, for example, ethylenically unsaturated compounds (e.g., (meth)acrylates, vinyl functional organosiloxanes, etc.) or epoxy functional materials. In some embodiments, such photoinitiator systems can include components such as a photoinitiator, a sensitizer, an electron donor, and/or an electron acceptor. Examples of such photoinitiator systems are described, for example, in U.S. Patent Application Publication No. 2004/0012872 (Fleming). Additional photoinitiator systems for polymerizing ethylenically unsaturated systems are disclosed in U.S. Pat. Nos. 5,145,886 (Oxman et al.), 6,046,250 (Boardman et al.), 4,916,169 (Boardman et al.), and 6,376,569 (Oxman et al.).

In other embodiments, photoinitiator systems that can induce polymerization in certain organosiloxane encapsulants are hydrosilylation catalysts as described, for example, in cofiled and commonly assigned U.S. Patent Application “Method of Making Light Emitting Device With Silicon-Containing Encapsulant”, Attorney Docket No. 60158US002, the entire contents of which are incorporated herein by reference. Exemplary hydrosilylation catalysts include, for example, bis(acetylacetonate)platinum, and the group of Pt(II) β-diketonate complexes (such as those disclosed in U.S. Pat. No. 5,145,886 (Oxman et al.), (η⁵-cyclopentadienyl)tri(σ-aliphatic)platinum complexes (such as those disclosed in U.S. Pat. No. 4,916,169 (Boardman et al.), and U.S. Pat. No. 4,510,094 (Drahnak)), and C₇₋₂₀-aromatic substituted (η⁵-cyclopentadienyl)tri(σ-aliphatic)platinum complexes (such as those disclosed in U.S. Pat. No. 6,150,546 (Butts)).

Light Emitting Diodes

The methods disclosed herein are useful with a wide variety of LEDs, including monochrome and phosphor-LEDs (in which blue or UV light is converted to another color via a fluorescent phosphor). LED emission light can be any light that an LED source can emit and can range from the UV to the infrared portions of the electromagnetic spectrum depending on the composition and structure of the semiconductor layers.

The methods described herein are particularly useful with near-UV to green emitting monochrome LEDs (about 400 nm to about 550 nm peak wavelength) since a wide variety of suitable photoinitiators and/or photosensitizers are absorbing in this wavelength range. The methods described herein are particularly useful in surface mount and side mount LED packages where the encapsulant is cured in a reflector cup. They are useful with a variety of LED architectures including top wire bond configurations and with flip-chip configurations. In flip-chip configurations, the LED die has both electrical contacts at the base thereof proximate the substrate, so the upper emitting surface of the die is usually fully emitting and unobstructed by any electrical contacts such as wire bonds, contact pads, and so forth. Additionally, the methods described herein can be useful for surface mount LEDs where there is no reflector cup and can be useful for encapsulating arrays of surface mounted LEDs attached to a variety of substrates.

The disclosed methods and encapsulants can also be used with phosphor-LEDs (PLED). Here an LED generates light in one range of wavelengths, which impinges upon and excites a phosphor material to produce visible light at other wavelengths. The phosphor can comprise a mixture or combination of distinct phosphor materials, and the light emitted by the phosphor can include a plurality of narrow emission lines distributed over the visible wavelength range such that the emitted light appears substantially white to the unaided human eye.

An example of a PLED is a blue LED illuminating a phosphor that converts blue to both red and green wavelengths. A portion of the blue excitation light is not absorbed by the phosphor, and the residual blue excitation light is combined with the red and green light emitted by the phosphor. Another example of a PLED is an ultraviolet (UV) LED illuminating a phosphor that absorbs and converts UV light to red, green, and blue light. It will be apparent to one skilled in the art that competitive absorption of the LED emission light by the phosphor will decrease absorption by the photoinitiator system slowing or preventing cure if the system is not carefully constructed. It will also be apparent that scattering of the LED emission light by phosphor materials may prevent formation of GRIN structures since the intensity distribution will tend to become uniform.

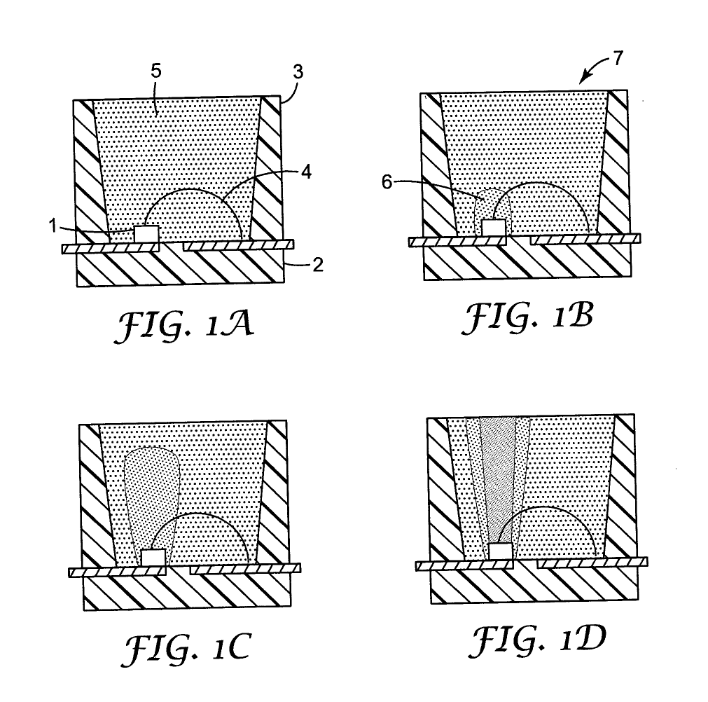

The following description is an illustrative embodiment in which the photopolymerizable encapsulant includes a polymerizable component and a non-polymerizable component, wherein the polymerizable component has a refractive index different than the refractive index of the non-polymerizable component, and one of the components migrates upon polymerization of the photopolymerizable component. Referring to FIG. 1A, LED 1 (depicted as an LED die) is mounted on a substrate 2 in a reflecting cup 3. The substrate 2 has two electrical contacts formed thereon, as shown in the figure, that can be used to energize the LED. The LED is also provided with electrical contacts (not shown), one on its lowermost surface and another on its uppermost (emitting) surface. The lowermost LED contact connects directly to one of the substrate electrical contacts, while the uppermost LED contact connects to the other substrate electrical contact by a wire bond 4. A power source can be coupled to the electrical contacts on the substrate to energize the LED. A volume of photopolymerizable encapsulant 5 covers and encapsulates the LED 1, as well as the wire bond 4. When the power source is turned on, the polymerization of the photopolymerizable encapsulant 5 begins around the diode 1 to form a polymerized cone 6 shown schematically in FIG. 1B, in which phase separation between the polymerizable component and the non-polymerizable component has occurred at least partially. As the illumination proceeds, polymerization can continue and the polymerized cone 6 can increase in the direction of the emitted light, as depicted in FIG. 1C. Finally, FIG. 1D depicts the LED package after the polymerized cone 6 has increased to the point where it reaches the air-encapsulant boundary 7 (see FIG. 1B). At this time, the light emitting article may be subjected to either an additional heating or illumination by an external light source, or both, to complete the cure of the photopolymerizable encapsulant 5.

Polymerization of the encapsulant can be accomplished under an air environment, or under an inert atmosphere such as nitrogen, argon, or helium. The use of an inert atmosphere can provide a more complete surface cure for certain encapsulant compositions.

Although FIGS. 1A-D show only one LED, the technique can easily be extended to arrays of one or more LEDs. Further, the diodes or arrays of diodes can be mounted on a substrate without a reflecting cup.

Several non-limiting examples will now be described. These should be interpreted broadly in accordance with the scope of the invention as claimed.

### EXAMPLES

Unless otherwise indicated, all parts and percentages are by weight and all molecular weights are weight average molecular weight.

### Abbreviations, Descriptions, and Sources of Materials

| | |
|---|---|
| | Bisphenol A diglycidylether dimethacrylate |
| | (Sigma-Aldrich, Milwaukee, WI) |
| PEG400DMA | Polyethylene glycol-400 dimethacrylate |
| | (Rhom Tech, Inc., Linden, NJ) |
| CDMA | (bis-isocyanatoethylmethacrylate derivative |
| | of citric acid, Prepared in accordance with |
| | the procedure described in the Examples |
| | section prior to Example 1 in U.S. Pat. No. |
| | 6,818,682 (Falsafi et al.), filed Apr. 20,2001.) |
| CDMA-PEGDMA | One part by weight CDMA dissolved in one |
| | part by weight PEGDMA |
| | Ethyl (4 dimethylamino)benzoate |
| | (Sigma-Aldrich, Milwaukee, WI) |
| BHT | 2,6-Di-tert-butyl-4-methylphenol |
| | (Sigma-Aldrich, Milwaukee, WI) |
| CPQ | Camphorquinone (Sigma-Aldrich, Milwaukee, WI) |
| | Diphenyliodonium Hexafluorophosphate |
| | (Sigma-Aldrich, Milwaukee, WI) |
| | Erythrosin B |
| | (Sigma-Aldrich, Milwaukee, WI) |
| | Erythrosin Y |
| | (Sigma-Aldrich, Milwaukee, WI) |
| | Erythrosin Yellow Blend |
| | (90% Erythrosin B and 10% Erythrosin Y) |
| | Vinyldimethylsiloxy-terminated |
| | polydimethylsiloxane |
| | (Dow Corning, Midland, MI) |
| | Dow Corning Syl-Off 7678 |
| | (trimethylsiloxy-terminated dimethylsiloxane |
| | methyl hydrogen siloxane copolymer) |
| | (Dow Corning, Midland, MI) |
| Pt(acac)₂ | Bis(acetylacetonate)platinum |
| | (Sigma-Aldrich, Milwaukee, WI) |
| | Cellulose Acetate Butyrate |
| | (Sigma-Aldrich, Milwaukee, WI) |
| SR-339 | 2-Phenoxyethyl Acrylate |
| | (Sartomer, West Chester, PA) |
| | 2-(1-Napthoxy)ethyl acetate |
| | (Prepared in accordance with the procedure |
| | described in the Examples section prior to |
| | Example 1 in U.S. Pat. No. 6,541,591 (Olson |
| | et al.), filed Dec. 21, 2000.) |
| SR-351 | Trimethylolpropane Triacrylate |
| | (Sartomer, West Chester, PA) |
| Irgacure 819 | bis(2,4,6-trimethylbenzoyl)phenyl phosphine |
| | oxide (Ciba Specialty Chemicals, Tarrytown, NY) |

Preparation of Blue LED Packages

Into a Kyocera Package (Kyocera America, Inc., Part No. KD-LA2707-A) was bonded a Cree XB die (Cree Inc., Part No. C460XB290-0103-A) using a water based halide flux (Superior No. 30, Superior Flux & Mfg. Co.). The LED package was completed by wire bonding (Kulicke and Soffa Industries, Inc. 4524 Digital Series Manual Wire Bonder) the Cree XB die using 1 mil gold wire. Prior to use each package was tested without encapsulation using an OL 770 Spectroradiometer (Optronics Laboratories, Inc.) with a constant current of 20 mA.

### Example 1

### Photobleaching Encapsulant For Green Or Blue LED

A mixture of 103.80 grams of bisphenol A diglycidylether dimethacrylate, 207.70 grams of PEG40DMA (a polyethyleneglycol-dimethacrylate), 1466.00 grams of a 1:1 mixture of CDMA (a carboxylated dimethacrylate) and PEG400DMA, 41.60 grams of ethyl (4 dimethylamino)benzoate, 9.24 grams of butylated hydroxytoluene, 9.26 grams of camphorquinone, 13.9 grams of diphenyliodonium hexafluorophosphate, and 0.46 grams of Erythrosin yellow blend (90% Erythrosin B and 10% Erythrosin Y) was prepared in a 5 liter round bottom flask. The resin was prepared under yellow light to avoid inadvertent photoreaction and was stored in a brown plastic Nalgene bottle.

### Example 2

### LED Curing Of Photobleachable Encapsulant

To a blue LED package was added approximately 2 milligrams of low viscosity, pink colored photoreactive methacrylate resin from Example 1. Electrical contact was made to the LED package and 20 milliamperes of current was passed through the LED. The LED was illuminated for approximately 2 minutes. The methacrylate resin encapsulant was completely cured, solid, and clear and light yellow in color with no visible pink color. The cured resin was substantially uniform in refractive index throughout its volume.

### Example 3

### Blue Light Cured Organosiloxane Encapsulant

A mixture of 10.00 grams (g) of the vinyl siloxane base polymer H₂C═CH—Si(CH₃)₂O—(Si(CH₃)₂O)₁₀₀—Si(CH₃)₂—CH═CH₂ (olefin milliequivalent weight (meq wt)=3.801 grams) and 0.44 g of the siloxane crosslinking agent (CH₃)₃SiO—(Si(CH₃)₂O)₁₅—(SiH(CH₃)O)₂₅—SiMe₃ (Dow Coming Syl-Off 7678, Si-H meq wt=0.111 g) was prepared in a 35 milliliter (mL) amber bottle. A catalyst stock solution as prepared by dissolving 22.1 mg of Pt(acac)₂ (wherein acac is acetoacetonate, purchased from Aldrich Chemical Company) in 1.00 mL of CH₂Cl₂, and a 100-microliter (μL) aliquot of this solution was added to the mixture of siloxane polymers. The final formulation was equivalent to a C═C/Si—H functionality ratio of 1.5 and contained approximately 100 ppm of Pt.

### Example 4

### LED Curing of Organosiloxane Encapsulant

Into a blue LED package (prepared as described above, peak emission wavelength 455-457 nm) was added approximately 2 milligrams (mg) of the above formulation from Example 3. The LED was illuminated for 2.5 minutes using a drive current of 20 milliamperes (mA). The encapsulated package was allowed to sit for an additional 5 minutes. The encapsulant was elastomeric and cured as determined by probing with the tip of a tweezers. The cured resin was substantially uniform in refractive index throughout its volume. The efficiency of the LED was measured using an OL 770 spectroradiometer and increased from 9.3% before encapsulation to 11.8% after encapsulation.

### Further Embodiment

The following steps can be followed to prepare a packaged LED having a cured encapsulant that is solid, slightly yellow in color, and self-aligned with the LED die (i.e., the refractive index of the encapsulant is non-uniform, and the nonuniformity corresponds at least roughly to the emission profile of the LED die). A solution (60% solids by weight in dichloroethane) containing 50% by weight cellulose acetate butyrate, 35% by weight 2-phenoxyethyl acrylate (available under the trade name SR-339 from Sartomer) 10% by weight 2-(1-napthoxy)ethyl acetate, 1% by weight trimethylolpropane triacrylate, 0.25% Irgacure 819 (Ciba) is prepared. The solution is dispensed using a microsyringe into the package containing an LED die that emits 405-nanometer light. Residual solvent is removed from the mixture by soft baking in an 80° C. oven for 30 minutes. Electrical contact is made to the external leads and 20 milliamperes of current is passed through the LED for approximately 10 minutes. The emission distribution of the emitted light is observed to change over the cure period. The encapsulated LED is then illuminated from the top with a UV lamp for 30 minutes to complete the cure.

The complete disclosure of all patents, patent applications, and publications, and electronically available material cited herein are incorporated by reference. The foregoing detailed description and examples have been given for clarity of understanding only. No unnecessary limitations are to be understood therefrom. The invention is not limited to the exact details shown and described, for variations obvious to one skilled in the art will be included within the invention defined by the claims.

What is claimed is:

1. A method of making a light emitting article, the method comprising:
providing an LED in a volume of a photopolymerizable encapsulant having a thickness; and
activating the light emitting diode to emit light to at least partially polymerize the entire thickness of the photopolymerizable encapsulant.

2. The method of claim 1, wherein the LED is provided in a mold, and the volume of the photopolymerizable encapsulant fills the mold.

3. The method of claim 2, wherein the mold is a reflector cup.

4. The method of claim 1, wherein the LED is provided on a substrate.

5. The method of claim 1, further comprising heating, irradiating with an external light source, or a combination thereof, to further polymerize the photopolymerizable encapsulant.

6. The method of claim 1, wherein the photopolymerizable encapsulant comprises a photoinitiator system.

7. The method of claim 6, wherein the photoinitiator system initially absorbs light of a wavelength emitted by the LED and subsequently bleaches.

8. The method of claim 1, wherein the photopolymerizable encapsulant comprises a polymerizable component and a non-polymerizable component.

9. The method of claim 8, wherein activating the LED to at least partially polymerize the photopolymerizable encapsulant provides at least partial phase separation of the polymerizable and non-polymerizable components.

10. The method of claim 8, wherein the polymerizable component is selected from the group consisting of epoxy functional materials, (meth)acrylate functional materials, organosiloxanes, and combinations thereof.

11. A method of making a light-emitting article, the method comprising:
providing an LED in a photopolymerizable encapsulant, wherein the photopolymerizable encapsulant comprises a polymerizable component and nanoparticles, and wherein the polymerizable component has a refractive index different than the refractive index of the nanoparticles; and
activating the LED to emit light to at least partially polymerize the photopolymerizable encapsulant.

12. The method of claim 11, wherein activating the LED to at least partially polymerize the photopolymerizable encapsulant allows the polymerizable component and the nanoparticles to at least partially phase separate, providing the encapsulant with a graded refractive index.

13. A method of making a light-emitting article, the method comprising:
providing an LED in a photopolymerizable encapsulant, wherein the photopolymerizable encapsulant comprises a polymerizable component and a polymer, and wherein the polymerizable component has a refractive index different than the refractive index of the polymer; and
activating the LED to emit light to at least partially polymerize the photopolymerizable encapsulant.

14. The method of claim 13, wherein activating the LED to at least partially polymerize the photopolymerizable encapsulant causes the polymerizable component and the polymer to phase separate at least partially, providing the encapsulant with a graded refractive index.

15. A method of making a light emitting article, the method comprising:
providing an LED in a photopolymerizable encapsulant wherein the photopolymerizable encapsulant comprises a polymerizable component and a non-polymerizable component, wherein the polymerizable component has a refractive index different than the refractive index of the non-polymerizable component, and wherein one of the components migrates upon polymerization of the photopolymerizable component; and
activating the LED to emit light to at least partially polymerize the photopolymerizable encapsulant.

16. The method of claim 15, wherein activating the LED to at least partially polymerize the photopolymerizable encapsulant allows the polymerizable component and the non-polymerizable component to phase separate at least partially, providing the encapsulant with a graded refractive index.

17. The method of claim 15, wherein the refractive index of the component that migrates is larger than the refractive index of the other component.

18. A method of bonding an encapsulated LED to a waveguide, the method comprising:
providing an LED in a photopolymerizable encapsulant;
contacting the waveguide with the photopolymerizable encapsulant; and
activating the LED to emit light to at least partially polymerize the photopolymerizable encapsulant.

19. A light emitting article comprising:
an LED; and
a self-aligned graded refractive index lens that substantially corresponds to the emission profile of the LED.

20. The light emitting article of claim 19 wherein the self-aligned graded refractive index lens comprises:
a polymerized component; and
nanoparticles having a refractive index different than the refractive index of the polymerized component.

21. The light emitting article of claim 19 wherein the self-aligned graded refractive index lens comprises:
a polymerized component; and
a polymer having a refractive index different than the refractive index of the polymerized component.
